(19) United States
(12) Patent Application Publication
(10) Pub. No.: US 2025/0048558 A1
(43) Pub. Date: Feb. 6, 2025

(54) DISPLAY DEVICE AND METHOD FOR PRODUCING SAME

(71) Applicant: Sharp Display Technology Corporation, Kameyama City, Mie (JP)

(72) Inventors: Takushi MIHOTANI, Kameyama City, Mie (JP); Tadashi NISHIOKA, Kameyama City, Mie (JP)

(21) Appl. No.: 18/696,256

(22) PCT Filed: Dec. 1, 2021
(86) PCT No.: PCT/JP2021/044049

§ 371 Date: Mar. 27, 2024

(51) Int. Cl. H05K 1/18; H10K 59/12; H10K 77/10; H10K 102/00

(52) U.S. Cl. CPC H05K 1/189; H10K 59/1201; H10K 77/111; H05K 2201/10128; H10K 2102/311

(57) ABSTRACT

An organic EL display device includes: an IC chip mounted through a first conductive material; and an FPC mounted through a second conductive material. The IC chip and the FPC are arranged side by side. Between the IC chip and the FPC, a partition wall member is provided to separate the first conductive material and the second conductive material from each other.

### TECHNICAL FIELD

The disclosure relates to a display device and a method for producing the display device.

### BACKGROUND ART

In recent years, light-emitting organic electroluminescence (EL) display devices using organic EL elements have attracted attention as a replacement for liquid crystal display devices. These organic EL display devices include flexible organic EL display devices. A proposed flexible organic EL display device has a flexible panel. The flexible panel includes: a display panel in which organic EL elements and various kinds of films are stacked on a flexible resin substrate; and electronic components including drive integrated-circuit (IC) chips and a flexible printed circuit (FPC). The electronic components are mounted either directly on the display panel, or indirectly over the display panel through a film substrate. The electronic components are mounted by compression bonding, using a conductive material (a conductive adhesive) such as a conductive paste or an anisotropic conductive film (ACF).

When a defect is found in the FPC mounted by compression bonding, a step is carried out to remove the defective FPC from the substrate and remount a new FPC (a rework step). At the rework step, the residue of the conductive material used for the mounting by compression bonding is adhered to the mark left by the removed defective FPC. Hence, a detaching solution is applied to the adhered residue in order to remove the residue. Here, the applied detaching solution might inadvertently be in contact with other electronic components (e.g., IC chips) adjacent to the defective FPC or with a conductive material used for the mounting by compression bonding. In this case, a similar conductive material is used also for mounting of the IC chips by compression bonding. Hence, the detaching solution might adversely affect the mounting (connection) condition of the IC chips, and the IC chips could cause a defect of the display device.

For example, Patent Document 1 proposes a flat display device in which two dummy pads, each of which is larger in size than the terminals for connecting a TCP, are disposed between mutually adjacent TCPs (branch wiring boards) connected to a PCB (a main wiring board) through an ACF, and the dummy pads are separated from each other by, for example, 1.5 mm or more. In the flat display device, the ACF is cut and removed in a region between the dummy pads, thereby preventing poor terminal connection caused by the spread of a solvent (the detaching solution) for removing the ACF in a repair (the rework step), and found at the connection between a TCP adjacent to another TCP to be reworked and the PCB.

### CITATION LIST

### Patent Literature

[Patent Document 1] Japanese Unexamined Patent Application Publication No. 2002-258767

### SUMMARY

### Technical Problems

However, as to the display device of Patent Document 1, if the distance is short (e.g., approximately 1 to 2 mm) between an electronic component (e.g., the FPC) to be reworked and another electronic component (e.g., an IC chip) adjacent to the electronic component, it is difficult to remove the residue while the detaching solution is kept from contact with the IC chip even if the ACF is cut and removed in the region between the dummy pads. Furthermore, if the two dummy pads, which are larger in size than the terminals, are spaced apart from each other at a predetermined distance or more, such a configuration goes against the trend of modularizing and downsizing a display panel included in the display device.

The disclosure is conceived in view of the above problems and provided for a display device in which an IC chip and a conductive material are adjacent to each other and mounted by compression bonding through a conductive material. The disclosure is set out to reduce poor connection of the IC chip caused when a detaching solution, for detaching residue of the conductive material, makes contact with the IC chip while the FPC is removed and remounted.

### Solution to Problems

In order to achieve the above object, a display device according to the disclosure includes: an IC chip mounted through a first conductive material; and an FPC mounted through a second conductive material. The IC chip and the FPC are arranged side by side. Between the IC chip and the FPC, a partition wall member is provided to separate the first conductive material and the second conductive material from each other.

In a method for producing a display device according to the disclosure, the display device includes: an IC chip mounted through a first conductive material; an FPC mounted side by side with the IC chip through a second conductive material; a partition wall member provided between the IC chip and the FPC, and separating the first conductive material and the second conductive material from each other; and an IC protective tape provided to cover the IC chip. The method includes an IC protective tape attaching step of attaching the IC protective tape to the IC chip. The partition wall member is formed at the IC protective tape attaching step.

In a method for producing a display device according to the disclosure, the display device includes: an IC chip mounted through a first conductive material; an FPC mounted side by side with the IC chip through a second conductive material; a partition wall member provided between the IC chip and the FPC, and separating the first conductive material and the second conductive material from each other; an IC protective tape provided to cover the IC chip; and a metal tape provided on the IC protective tape to cover the IC chip. The partition wall member is integrally formed with the metal tape. The method includes: an IC protective tape attaching step of attaching the IC protective tape to the IC chip; and a metal tape attaching step of attaching the metal tape to the IC chip to which the IC protective tape is attached. At the metal tape attaching step, the metal tape is attached to form the partition wall member.

### Advantageous Effects

The disclosure is provided for a display device in which an IC chip and a conductive material are adjacent to each other and mounted by compression bonding through a conductive material. The disclosure can reduce poor connection of the IC chip caused when a detaching solution, for detaching residue of the conductive material, makes contact with the IC chip while the FPC is removed and remounted.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a cross-sectional view of a terminal unit of the organic EL display device according to the first embodiment of the disclosure, taken along line III-III in FIG. 1.

FIG. 4 is a cross-sectional view of the terminal unit in a modification of the organic EL display device according to the first embodiment of the disclosure. FIG. 4 corresponds to FIG. 3.

FIG. 5 is a perspective view showing a step of installing a partition wall member included in the organic EL display device according to the first embodiment of the disclosure.

FIG. 6 is a perspective view showing a rework step of detaching and remounting an FPC included in the organic EL display device according to the first embodiment of the disclosure.

FIG. 7 is a cross-sectional view of a terminal unit of an organic EL display device according to a second embodiment of the disclosure. FIG. 7 corresponds to FIG. 3.

FIG. 8 is a perspective view showing a step of installing a partition wall member included in the organic EL display device according to the second embodiment of the disclosure. FIG. 8 corresponds to FIG. 5.

FIG. 9 is a cross-sectional view of a terminal unit of an organic EL display device according to a third embodiment of the disclosure. FIG. 9 corresponds to FIG. 3.

FIG. 10 is a perspective view showing a step of installing a partition wall member included in the organic EL display device according to the third embodiment of the disclosure. FIG. 10 corresponds to FIG. 5.

FIG. 11 is a perspective view showing a rework step of detaching and remounting an FPC included in the organic EL display device according to the third embodiment of the disclosure. FIG. 11 corresponds to FIG. 6.

FIG. 12 is a plan view of a schematic configuration of an organic EL display device according to a fourth embodiment of the disclosure. FIG. 12 corresponds to FIG. 1.

### DESCRIPTION OF EMBODIMENTS

Embodiments of the disclosure will be described in detail below with reference to the drawings. Note that the disclosure shall not be limited to the embodiments below.

### First Embodiment

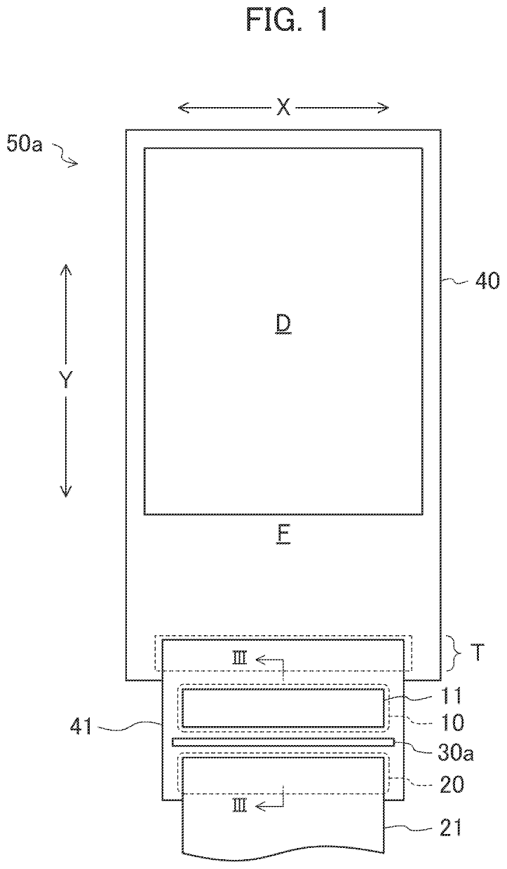

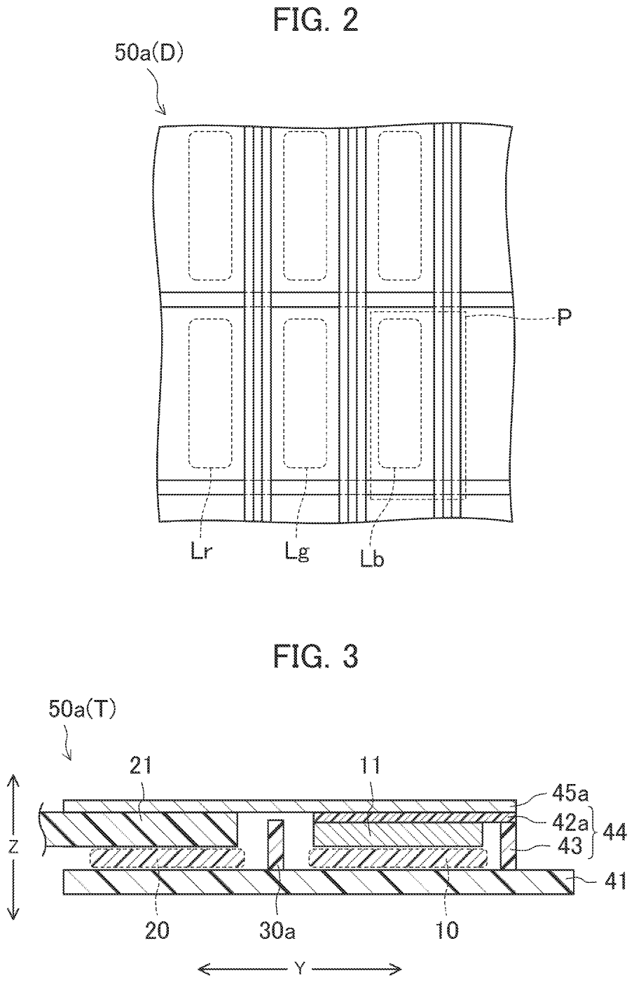

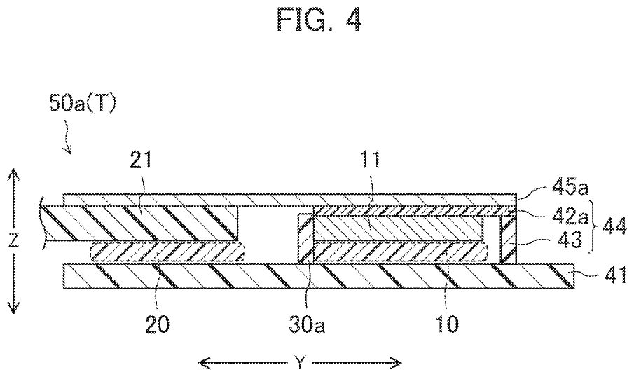

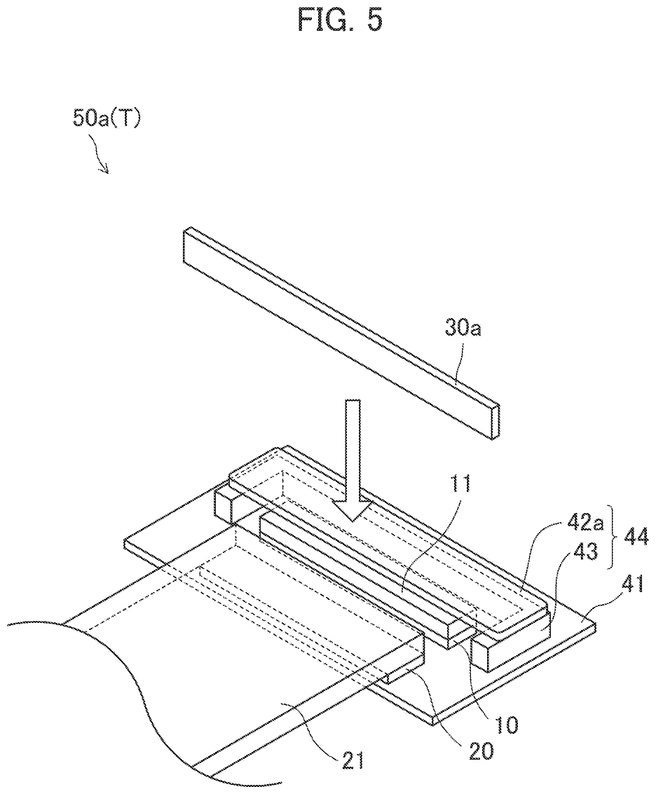

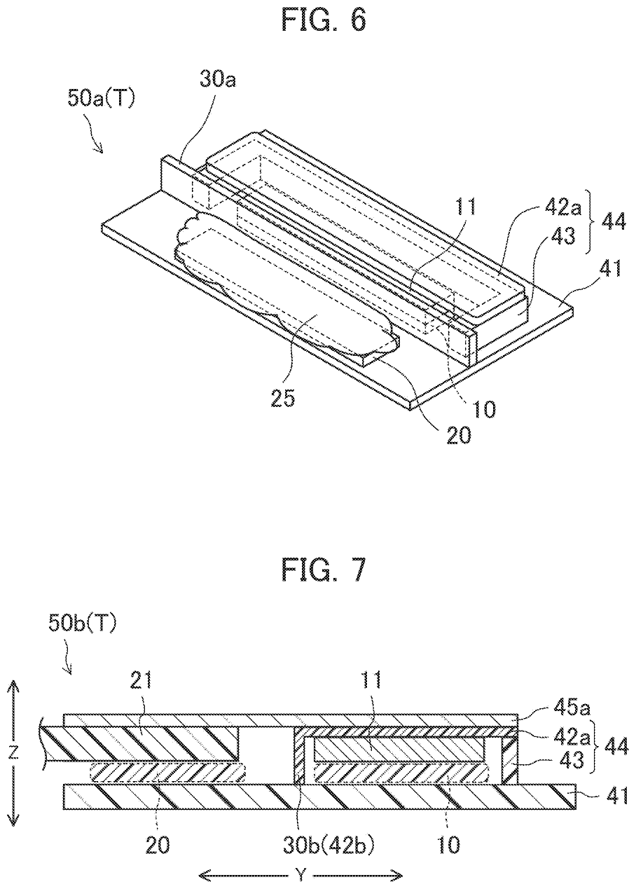

FIGS. 1 to 6 illustrate a first embodiment of a display device according to the disclosure. In the embodiments below, an organic EL display device including an organic EL element is exemplified as a display device including a light-emitting element. Here, FIG. 1 is a plan view of a schematic configuration of an organic EL display device 50a according to this embodiment. FIG. 2 is a plan view of a display region D of the organic EL display device 50a. FIG. 3 is a cross-sectional view of a terminal unit T of the organic EL display device 50a, taken along line III-III in FIG. 1. FIG. 4 is a cross-sectional view of the terminal unit T in a modification of the organic EL display device 50a. FIG. 4 corresponds to FIG. 3. FIG. 5 is a perspective view showing a step of installing a partition wall member 30a included in the organic EL display device 50a. FIG. 6 is a perspective view showing a rework step of detaching and remounting an FPC 21 included in the organic EL display device 50a.

The organic EL display device 50a illustrated in FIG. 1 includes a display panel 40 having, for example: the display region D shaped into a rectangle and displaying an image; and a picture-frame region F shaped into a picture frame and provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides. Note that, in the organic EL display device 50a, a direction X (see FIG. 1), a direction Y (see FIGS. 3 and 4), and a direction Z (see FIGS. 3 and 4) are defined. The direction X is in parallel with a surface of a substrate included in the display panel 40. The direction Y is perpendicular to the direction X and in parallel with the surface of the substrate. The direction Z (see FIGS. 3 and 4) is perpendicular to the direction X and the direction Y.

The display region D illustrated in FIG. 2 includes a plurality of subpixels P arranged in a matrix. Moreover, in the display region D, as illustrated in FIG. 2, for example, subpixels P having red light-emitting regions Lr for presenting red, subpixels P having green light-emitting regions Lg for presenting green, and subpixels P having blue light-emitting regions Lb for presenting blue are provided side by side. Note that, in the display region D, for example, neighboring three subpixels P each having one of a red light-emitting region Lr, a green light-emitting region Lg, and a blue light-emitting region Lb constitute one pixel.

The picture-frame region F in FIG. 1 has a lower end portion provided with a terminal unit T extending in a horizontal direction (in the direction X) of FIG. 1.

The terminal unit T illustrated in FIG. 1 is provided with a flexible substrate 41. The flexible substrate 41 has an end mounted on the terminal unit T. The flexible substrate 41 is a film substrate formed of, for example, a polyimide resin. The flexible substrate 41 is electrically connected to the terminal unit T through a conductive material (not shown). Examples of the conductive material include a conductive paste and the ACF.

On the flexible substrate 41, as illustrated in FIGS. 1 and 3, an IC chip 11 is mounted. That is, the flexible substrate 41 is also referred to as a chip-on-film (COF) that is a film substrate on which the IC chip 11 is mounted. Hereinafter, the flexible substrate 41 on which the IC chip 11 is mounted is also referred to as a “COF 41”.

Furthermore, on the COF 41, an FPC 21 is mounted as illustrated in FIGS. 1 and 3. The FPC 21 is a film substrate on which various functional components are mounted except for the IC chip 11. The FPC 21 is distinguished from the COF 41 on which the IC chip 11 is mounted. That is, the COF 41 is also referred to as a film-on-film (FOF)-mounted COF (a film substrate) on which the FPC 21 (a film substrate) is mounted. Hereinafter, the COF 41 on which the FPC 21 is mounted is also referred to as an “FOF-mounted COF 41”.

The IC chip 11 is, as illustrated in FIGS. 1 and 3, mounted on (i.e., electrically connected to) the flexible substrate 41 through a first conductive material 10. Examples of the first conductive material 10 include a conductive paste and the ACF. The first conductive material 10 is preferably formed of the ACF.

The FPC 21 is, as illustrated in FIGS. 1 and 3, mounted on (i.e., electrically connected to) the COF 41 through a second conductive material 20. Examples of the second conductive material 20 include a conductive paste and the ACF. The second conductive material 20 is preferably formed of the ACF.

The FPC 21 and the IC chip 11 are, as illustrated in FIGS. 1 and 3, arranged side by side in the direction Y Specifically, the IC chip 11 and the FPC 21 are arranged in order from toward the display region D to toward the terminal unit T. The IC chip 11 and the FPC 21 are apart from each other for any given distance, and the distance is, for example, 4 mm or less. Note that, in order to downsize a module of the display panel 40, the distance is approximately 1 to 2 mm.

As illustrated in FIGS. 1 and 3, the first conductive material 10 and the second conductive material 20 are individually provided to serve as conductive materials for mounting the IC chip 11 and the FPC 21 on the flexible substrate 41. That is, the IC chip 11 and the FPC 21 are mounted on the flexible substrate 41 through the respective conductive materials. In other words, a common conductive material is not used as the conductive material for mounting the IC chip 11 and the FPC 21 on the flexible substrate 41.

Over the IC chip 11, an IC protective tape 44 is provided as illustrated in FIGS. 3 to 6. (In FIG. 1, the IC protective tape 44 is omitted.) The IC protective tape 44 is provided for protecting the IC chip 11. The IC protective tape 44 is provided to cover the IC chip 11. The IC protective tape 44 includes: a tape body 42a; and a spacer 43.

The tape body 42a protects an upper surface of the IC chip 11. Hence, as illustrated in FIGS. 3 to 6, the tape body 42a is provided to cover the upper surface of the IC chip 11. The tape body 42a is formed substantially the same in size (area) as, or slightly larger in size (area) than, the IC chip 11. Specifically, as illustrated in FIGS. 3 and 4, the tape body 42a has an end portion provided toward the display region D (i.e., an end portion provided across from an end portion toward the FPC 21) and protruding from the IC chip 11 (an end portion of the IC chip 11) in the direction Y The tape body 42a is formed larger than the IC chip 11. The tape body 42a is made of, for example, a resin film such as transparent polyethylene terephthalate (PET).

Furthermore, the tape body 42a is an adhesive tape whose lower surface is formed as an adhesive face. For this reason, the spacer 43 is attached to the lower surface (the adhesive face) of the tape body 42a. Thus, the tape body 42a and the spacer 43 integrally form the IC protective tape 44.

The spacer 43 is a reinforcing material for preventing the IC chip 11 from breakage or damage due to stress. Hence, the spacer 43 is provided around the IC chip 11. Specifically, as illustrated in FIGS. 3 to 6, the spacer 43 is provided to surround end portions (three sides) of the IC chip 11 except for an end portion toward the FPC 21 (i.e., an end portion facing the FPC 21). The spacer 43 is formed in a backward C-shape (a U-shape) in plan view. In other words, the spacer 43 is formed to have an opening toward the FPC 21 in the direction Y.

The spacer 43 is made of a resin material having relatively high hardness, such as, for example, a PET film (model Lumirror (registered trademark) X30 having a thickness of 0.2 mm and manufactured by Toray Industries, Inc.). The upper surface and the lower surface of the spacer 43 may be formed as adhesive faces. Alternatively, the upper surface and the lower surface do not have to be adhesive. If the lower surface of the spacer 43 does not serve as an adhesive face, the lower surface of the spacer 43 and the upper surface of the FOF-mounted COF 41 do not have to be in close contact with each other. Between the lower surface of the spacer 43 and the upper surface of the FOF-mounted COF 41, there may be a clearance sufficiently smaller than a thickness of the first conductive material 10.

The spacer 43 has any given lengths in the direction X and the direction Y, and the lengths may be determined as appropriate in accordance with the size of the IC chip 11. The spacer 43 has any given thickness (width) of, for example, 150 μm or more. The spacer 43 has any given height (i.e., a length in the direction Z in FIG. 3), and the height may be determined as appropriate in accordance with the thicknesses of the first conductive material 10 and the IC chip 11.

As illustrated in FIGS. 3 and 4, a metal tape 45a is provided over the IC chip 11 to which the IC protective tape 44 is attached. (In FIG. 1, the metal tape 45a is omitted). The metal tape 45a blocks the IC chip 11 from an electromagnetic wave. Hence, the metal tape 45a is provided to cover at least the upper surface of the IC chip 11. Note that, as illustrated in FIGS. 3 and 4, the metal tape 45a may be provided to cover the upper surface of the FPC 21 over the FOF-mounted COF 41 (i.e., a portion overlapping with the FOF-mounted COF 41 in plan view). In other words, the metal tape 45a is provided to cover the FOF-mounted COF 41. In this case, the metal tape 45a protects the upper surface of the FOF-mounted COF 41.

The metal tape 45a is integrally made of, for example, a resin film such as transparent polyethylene terephthalate (PET) and a metal foil provided to the resin film. The metal tape 45a is an adhesive tape whose lower surface is formed as an adhesive face. Hence, as illustrated in FIGS. 3 and 4, the metal tape 45a is attached to: the IC protective tape 44 attached to the IC chip 11; and the FPC 21.

The lower surface of the FOF-mounted COF 41 may be provided with a back surface tape (not shown). In this case, the back surface tape protects the lower surface of the FOF-mounted COF 41.

Here, as illustrated in FIGS. 1 and 3, the organic EL display device 50a includes a partition wall member 30a provided between the IC chip 11 and the FPC 21. If the FPC 21 mounted on the FOF-mounted COF 41 is defective, a step is carried out to detach the defective FPC 21 and remount a new FPC 21. (Hereinafter, the step is also referred to as an “FOF rework step” because the step involves rework of the FOF mounting.) At the FOF rework step, a residue of the second conductive material 20 (used for connecting the defective FPC 21 by compression bonding) is left in a mark made after the defective FPC 21 is detached. The residue has to be removed. Hence, a detaching solution 25; that is, a solvent to remove the residue, is applied to the mark, of the mounted defective FPC 21, to which the residue of the second conductive material 20 is adhered. Here, the partition wall member 30a functions as a barrier that prevents the detaching solution 25 from making contact with, and adhering to, the IC chip 11 (i.e., specifically, the first conductive material 10 used for connecting the IC chip 11 by compression bonding) adjacent to the mark of the mounted defective FPC 21. That is, the partition wall member 30a is a wall (a separator) to prevent intrusion of the detaching solution at the FOF rework step. The partition wall member 30a is a separator that separates the first conductive material 10 and the second conductive material 20 from each other.

Note that, as illustrated in FIGS. 3 to 6, the partition wall member 30a, together with the spacer 43, surrounds the entire circumference (four sides) of the IC chip 11. Specifically, the partition wall member 30a is provided to face the opening of the spacer 43 (the end portion of the IC chip 11 toward the FPC 21). Hence, the partition wall member 30a also functions as a portion of a reinforcing member included in the spacer 43 and provided to the IC chip 11.

The partition wall member 30a illustrated in FIGS. 3 to 6 is shaped into a shape of tape extending in the direction X (see FIG. 1) perpendicular to the direction Y in which the IC chip 11 and the FPC 21 face each other. The partition wall member 30a shaped into a shape of tape is formed of, for example, the same material as the material of the spacer 43. Hence, the partition wall member 30a shaped into a shape of tape has any given thickness (i.e., a length in the direction Y in FIGS. 1 and 3) of, for example, 150 μm or more. Note that the partition wall member 30a shaped into a shape of tape has any given longitudinal length (i.e., a long side in the direction X in FIG. 1). The longitudinal length may be determined as appropriate in accordance with the length of the IC chip 11 in the direction X. The partition wall member 30a shaped into a shape of tape has any given transverse length (i.e., a short side in the direction Z in FIG. 3). The transverse length may be determined as appropriate in accordance with the thicknesses of the first conductive material 10 and the IC chip 11 (in accordance with the length in the direction Z in FIG. 3). The transverse length may be at least the same as, or greater than, the height of the IC chip 11.

The partition wall member 30a is, as illustrated in FIG. 3, provided on the FOF-mounted COF 41. Specifically, the partition wall member 30a stands, on the upper surface of the FOF-mounted COF 41, away from each of the IC chip 11 and the FPC 21 (i.e., the first conductive material 10 and the second conductive material 20 for connecting the IC chip 11 and the FPC 21 by compression bonding). The partition wall member 30a shaped into a shape of tape is erected as an upright wall having one surface defined by longitudinal sides and thickness sides and serving as a bottom surface (a lower surface). Hence, a lower limit of the distance between the IC chip 11 and the FPC 21 described above is equal to, or greater than, the thickness of the partition wall member 30a.

The partition wall member 30a is, as illustrated in FIG. 3, secured to the upper surface of the FOF-mounted COF 41. Hence, the partition wall member 30a continues to stand as an upright wall. Exemplary techniques of securing together the lower surface of the partition wall member 30a and the upper surface of the FOF-mounted COF 41 include: a technique of forming the lower surface of the partition wall member 30a as an adhesive face, attaching the lower surface to the upper surface of the FOF-mounted COF 41, and adhesively securing the upper surface and the lower surface together; and a technique of applying in advance a curable resin (an adhesive), which cures by heat, ultraviolet rays, moisture, or oxygen insulation, to a portion including the lower surface of the partition wall member 30a or the upper surface of the FOF-mounted COF 41 and provided to secure the partition wall member 30a, allowing the curable resin to cure, and adhesively securing the upper surface and the lower surface together.

The partition wall member 30a is, as illustrated in FIG. 3, spaced apart from the metal tape 45a. That is, the partition wall member 30a is not secured to the lower surface (the adhesive face) of the metal tape 45a. Note that the partition wall member 30a and the metal tape 45a may be in contact with each other as long as the partition wall member 30a and the metal tape 45a are not secured together.

### Modification of First Embodiment

Note that, as illustrated in FIG. 4, the partition wall member 30a may be spaced apart from the FPC 21; whereas, the partition wall member 30a may stand on the upper surface of the FOF-mounted COF 41 to be in contact with the IC chip 11. Specifically, the partition wall member 30a may be adhesively secured to at least a portion of a side surface (toward the FPC 21) of the IC chip 11. In this case, the partition wall member 30a has a side surface toward the IC chip 11, and the side surface is formed as an adhesive face. Note that the partition wall member 30a may have a lower surface formed as an adhesive face. Alternatively, the lower surface do not have to be adhesive. If the lower surface of the partition wall member 30a does not serve as an adhesive face, the lower surface of the partition wall member 30a and the upper surface of the FOF-mounted COF 41 do not have to be in close contact with each other. Between the lower surface of the partition wall member 30a and the upper surface of the FOF-mounted COF 41, there may be a clearance sufficiently smaller than the thickness of the first conductive material 10. In this case, too, the detaching solution 25 is kept from entering from the clearance toward the IC chip 11 because the detaching solution 25 is a relatively highly viscous solution or a paste.

The modification of the organic EL display device 50a, that is, the configuration in which the side surface of the partition wall member 30a toward the IC chip 11 is formed as an adhesive face, can be applied to an embodiment to be described later.

As can be seen, the organic EL display device 50a includes: the IC chip 11 and the FPC 21 adjacent to each other; and the partition wall member 30a disposed between the IC chip 11 and the FPC 21. The partition wall member 30a is provided as a separator that separates the first conductive material 10 and the second conductive material 20 from each other. The first conductive material 10 and the second conductive material 20 are used for respectively mounting the IC chip 11 and the FPC 21. Note that, as to the organic EL display device 50a, the IC chip 11, the FPC 21, and the partition wall member 30a are mounted on the flexible substrate 41 connected to the terminal unit T in the picture-frame region F of the display panel 40.

Described next will be a method for producing the organic EL display device 50a of this embodiment and the modification of the organic EL display device 50a. The method for producing the organic EL display device 50a includes an IC protective tape attaching step. Furthermore, the method for producing the organic EL display device 50a includes, before the IC protective tape attaching step, a COF compression-bonding step and an FPC mounting step.

### COF Compression-Bonding Process

On the terminal unit T of the display panel 40, the flexible substrate 41 (the COF 41) is mounted. Here, the flexible substrate 41 has the IC chip 11 mounted thereon through the first conductive material 10. Specifically, on the terminal unit T, the COF41 is mounted by thermocompression-bonding through another conductive material different from the first conductive material 10 and the second conductive material 20.

### FPC Mounting Step

On the COF 41, the FPC 21 is FOF-mounted by thermocompression-bonding through the second conductive material 20. Hence, the FOF-mounted COF 41 is formed. That is, the FPC mounting step can be referred to as an FOF-mounting step of mounting the FPC 21 on the COF 41.

### IC Protective Tape Attaching Step

On the IC chip 11, the IC protective tape 44 is attached. Specifically, using, for example, a jig, the tape body 42a included in the IC protective tape 44 is attached to the upper surface of the IC chip 11 so that the spacer 43 included in the IC protective tape 44 surrounds the three sides of the IC chip 11 except for the end portion of the IC chip 11 toward the FPC 21.

Next, as illustrated in FIG. 5, the partition wall member 30a is provided between the IC chip 11 and the FPC 21. Specifically, the lower surface of the partition wall member 30a, which is shaped into a shape of tape, is attached (adhesively secured), or secured with an adhesive, to the FOF-mounted COF 41 between the first conductive material 10 and the second conductive material 20, so that the partition wall member 30a is erected as an upright wall. Because the partition wall member 30a and the FOF-mounted COF 41 are in close contact with each other, the first conductive material 10 and the second conductive material 20 are separated from each other. As can be seen, in the method for producing the organic EL display device 50a, the partition wall member 30a is formed at the IC protective tape attaching step.

### Other Steps

The method for producing the organic EL display device 50a may include, as necessity, other steps such as a metal tape attaching step, a back-face tape attaching step, and a rework step.

### Metal Tape Attaching Step

The metal tape attaching step is carried out after the IC protective tape attaching step. At the metal tape attaching step, the metal tape 45a is attached to the FOF-mounted COF 41 to which the IC protective tape 44 is attached. Specifically, using, for example, a jig, the metal tape 45a is attached to: the IC protective tape 44 (specifically, the tape body 42a included in the IC protective tape 44) attached to the IC chip 11; and the FPC 21. As a result, the IC chip 11 is covered with the metal tape 45a through the IC protective tape 44, and thus is blocked from an electromagnetic wave.

### Back-Face Tape Attaching Step

If the organic EL display device 50a includes a back-face tape, the back-face tape attaching step may be carried out. At the back-face tape attaching step, using, for example, a jig, the back-face tape is attached to a back face across from the face (the front face) to which the metal tape 45a of the FOF-mounted COF 41 is attached. Note that the back-face tape attaching step may be carried out either before or after the IC protective tape attaching step or the metal tape attaching step.

### Rework Step

If the FPC 21 mounted at the FPC mounting step is defective, the rework step is carried out. The rework step involves detaching the defective FPC 21 from the FOF-mounted COF 41 and remounting a new FPC 21 on the COF 41. That is, the rework step is an FOF rework step of reworking including mounting the FOF.

The FOF rework step includes: a metal tape detaching step; an FPC detaching step, a detaching solution applying step; a second conductive material removing step; and an FPC remounting step. Note that the FOF rework step may include a back-face tape detaching step if the method for producing the organic EL display device 50a includes the back-face tape detaching step. Furthermore, at the FOF rework step, the IC protective tape 44 does not particularly interfere with the work. Hence, a step of detaching the IC protective tape 44 is omitted.

### Metal Tape Detaching Step

The metal tape 45a attached at the metal tape attaching step is detached from the IC protective tape 44 and the FPC 21. The partition wall member 30a is adhesively secured, or secured with an adhesive, to the FOF-mounted COF 41, but is not adhesively secured to the metal tape 45a. Hence, when the metal tape 45a is detached, the partition wall member 30a is less likely to detach from the FOF-mounted COF 41.

Note that, at the metal tape detaching step, the IC protective tape 44 is kept from detaching from the IC chip 11. If the IC protective tape 44 is detached from the IC chip 11, the IC protective tape attaching step may be carried out again after the FOF rework step.

### Back-Face Tape Detaching Step

If the back-face attaching step is carried out, the back-face tape is detached from the FOF-mounted COF 41.

### FPC Detaching Step

The defective FPC 21 is detached from the FOF-mounted COF 41. Specifically, while heat is applied to a portion, of the FOF-mounted COF 41, on which the defective FPC 21 is mounted, the defective FPC 21 is detached.

### Detaching Solution Applying Step

The detaching solution 25 is applied to the mark on which the detective FPC 21 was mounted. Specifically, the detaching solution 25 is applied to cover the residue, of the second conductive material 20, left on the mark on which the detective FPC 21 was mounted. Note that the detaching solution 25 may be a commercially available product used in common. Examples of the detaching solution 25 (a repair solution) for the ACF include, for example, a solution model RP-04 manufactured by Hitachi Chemical Company, Ltd.

As illustrated in FIG. 6, when the detaching solution 25 is applied (specifically, in a sequence of the rework step), the partition wall member 30a is found on the COF 41. The partition wall member 30a functions as a wall for preventing the detaching solution 25 from entering toward the IC chip 11. The partition wall member 30a reduces the risk that the detaching solution 25 comes into contact with, and adheres to, the IC chip 11 and the first conductive material 10 while the detaching solution applying step is carried out.

### Second Conductive Material Removing Step

After a predetermined time period has passed since the application of the detaching solution, the residue of the second conductive material 20, which sticks to the mark of the portion on which the defective FPC 21 was mounted, is scrubbed and removed with, for example, a cotton swab or a spatula. Specifically, the residue of the second conductive material 20 swollen and lifted by the detaching solution 25 is wiped off together with the detaching solution 25, and cleaned. The partition wall member 30a reduces the risk that the detaching solution 25 comes into contact with, and adheres to, the IC chip 11 and the first conductive material 10 while the second conductive material removing step is also carried out.

### FPC Remounting Step

Using a new FPC 21, the same step as the FPC mounting step is carried out. Specifically, on the mark of a portion, of the COF 41, on which the defective FPC 21 was mounted, a new FPC 21 is thermocompression-bonded and FOF-remounted through a new second conductive material 20.

After the sequence of the rework step, such steps as the metal tape attaching step and the back-face tape attaching step are carried out as necessity. As can be seen, the organic EL display device 50a of this embodiment is successfully produced.

### Advantageous Effects

As described above, the organic EL display device 50a (including the modification) and the method for producing the organic EL display device 50a can achieve the advantageous effects below.

The organic EL display device 50a includes: the IC chip 11 mounted through the first conductive material 10; the FPC 21 mounted through the second conductive material 20; and the partition wall member 30a provided between the IC chip 11 and the FPC 21, and separating the first conductive material 10 and the second conductive material 20 from each other. The partition wall member 30a functions as a wall (a separator) for preventing the detaching solution 25, used for removing the residue of the second conductive material 20, from making contact with the IC chip 11 or the first conductive material 10. Even if, as to the structure of the display panel, the IC chip 11 and the FPC 21 are disposed adjacent to each other, and the distance between the IC chip 11 and the FPC 21 is relatively short, the partition wall member 30a reduces the risk that the portion on which the IC chip 11 is mounted is eroded by the detaching solution 25. Such a feature can reduce poor connection of the IC chip 11 to be caused when the detaching solution 25 is in contact with the IC chip 11.

As to the method for producing the organic EL display device 50a, the partition wall member 30a can be formed at a known IC protective tape attaching step included in the method. Hence the organic EL display device 50a can be easily produced.

Furthermore, as to the method for producing the organic EL display device 50a, the partition wall member 30a is found on the FOF-mounted COF 41 when, at the rework step, the detaching solution 25 is applied to the mark on which the defective FPC 21 was mounted (i.e., the detaching solution applying step). Hence, at the detaching solution applying step and the following second conductive material removing step, works such as application of the detaching solution and removal of the residue can be carried out without concern for the contact of the detaching solution 25 with the portion on which the IC chip 11 is mounted. In other words, the rework step can be carried out more efficiently.

As to the organic EL display device 50a and the method for manufacturing the organic EL display device 50a, the rework is reliably provided to a module in any structure, thereby successfully improving reliability (quality) of the display device.

### Second Embodiment

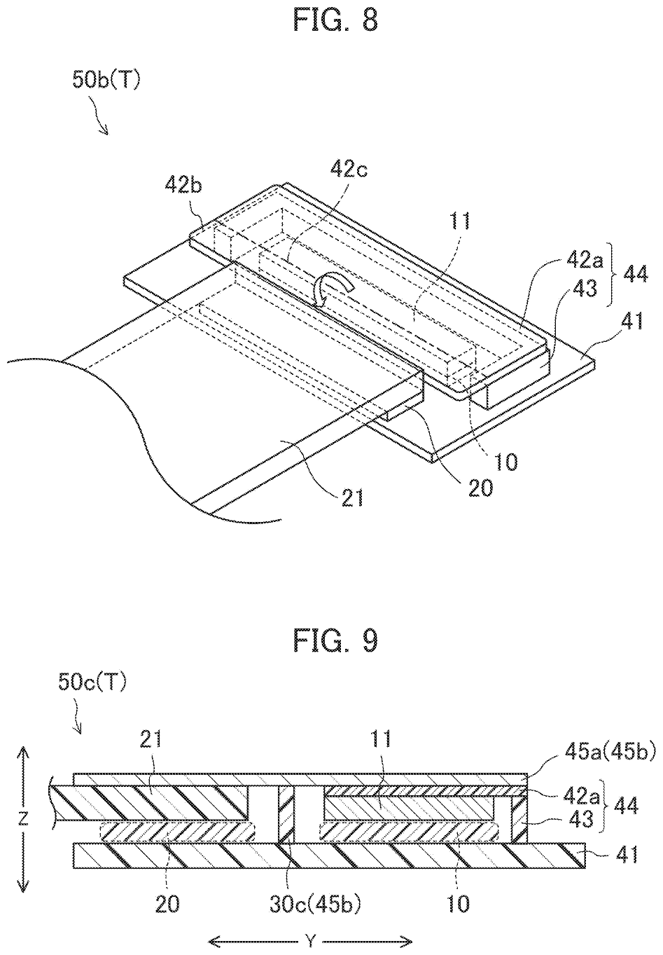

Next, a second embodiment of the disclosure will be described. FIGS. 7 and 8 illustrate a display device according to a second embodiment of the disclosure. FIG. 7 is a cross-sectional view of the terminal unit T of an organic EL display device 50b according to this embodiment. FIG. 7 corresponds to FIG. 3. FIG. 8 is a perspective view showing a step of installing a partition wall member 30b included in the organic EL display device 50b. FIG. 8 corresponds to FIG. 5.

The overall configuration of the organic EL display device 50b is the same as that of the organic EL display device 50a according to the first embodiment except for the configuration of the terminal portion T, and a detailed description thereof will be omitted. Furthermore, like reference signs designate identical constituent features between this embodiment and the first embodiment. Such constituent features will not be elaborated upon.

The organic EL display device 50b includes, as illustrated in FIGS. 7 and 8, the partition wall member 30b instead of the partition wall member 30a included in the organic EL display device 50a of the first embodiment. Moreover, the configuration of the IC protective tape 44 for the organic EL display device 50b is different from that for the organic EL display device 50a.

In the organic EL display device 50b, as illustrated in FIG. 8, the tape body 42a included in the IC protective tape 44 has an end portion toward the FPC 21, and the end portion is provided with a protruding portion 42b protruding in the direction Y (toward the FPC 21). Between the protruding portion 42b and the tape body 42a, a folding axis is defined in the direction X (see FIG. 1) perpendicular to the direction Y in which the IC chip 11 and the FPC 21 face each other. Specifically, along the folding axis, a slit (a cut) 42c is formed so that the protruding portion 42b is easily folded. Thanks to such a feature, the protruding portion 42b can be folded at 900 (right angle) to the tape body 42a.

When the protruding portion 42b is folded at 90° along the slit 42c in the direction of the arrow illustrated in FIG. 8, the partition wall member 30b is formed as illustrated in FIG. 7. Hence, the partition wall member 30b is formed of, for example, the same material as the material of the tape body 42a.

The partition wall member 30b may have a lower surface formed as an adhesive face and adhesively secured to the FOF-mounted COF 41. Alternatively, as described above, the lower surface may be secured with an adhesive to the FOF-mounted COF 41. Furthermore, the organic EL display device 50b may adopt the modification of the organic EL display device 50a. That is, a side surface of the partition wall member 30b toward the IC chip 11 may be formed as an adhesive face.

The organic EL display device 50b of this embodiment can be produced by modifying, as follows, the IC protective tape attaching step in the method for producing the organic EL display device 50a of the first embodiment.

### IC Protective Tape Attaching Step

At the IC protective tape attaching step, the IC protective tape 44 is attached to the IC chip 11. After that, instead of separately providing the partition wall member 30b, the protruding portion 42b is folded at 900 along the slit 42c in the direction of the arrow illustrated in FIG. 8.

As can be seen, the protruding portion 42b is simply folded to form the partition wall member 30b. Hence, the IC protective tape 44 may be attached so that, for example, the slit 42c (the folding axis) is laid along an end portion (a side) of the IC chip 11 toward the FPC 21.

### Advantageous Effects

As described above, the organic EL display device 50b according to this embodiment can achieve the same advantageous effects described in the first embodiment. Furthermore, in addition to the above advantageous effects, the organic EL display device 50b can achieve advantageous effects below.

In the organic EL display device 50b, the protruding portion 42b included in the IC protective tape 44 forms the partition wall member 30b. Such a feature eliminates the need for separately providing the partition wall member 30b. In other words, the feature can reduce the number of components.

In the method for producing the organic EL display device 50b, at the IC protective tape attaching step, the protruding portion 42b is simply folded with respect to the tape body 42a to form the partition wall member 30b. That is, compared with a case where the IC protective tape 44 and the partition wall member 30a are individually attached, the attaching work is carried out only once for the IC protective tape 44 alone. Such a feature can improve efficiency in the attaching work at the IC protective tape attaching step. In addition, compared with a case where the partition wall member 30a is secured with an adhesive, this step is omitted. Hence, the same advantageous effects can be achieved.

### Third Embodiment

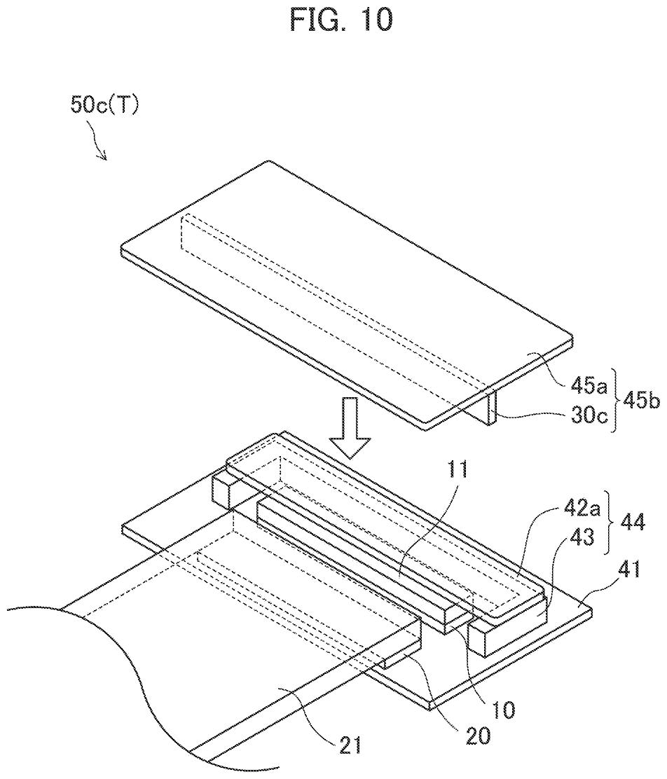

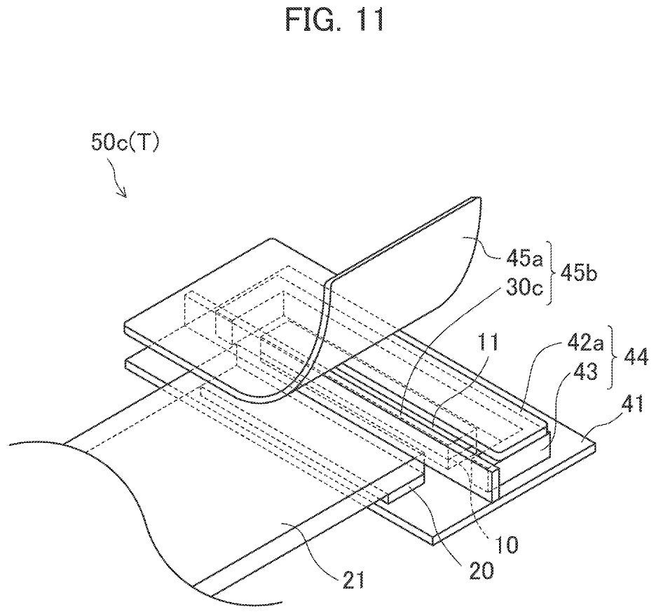

Next, a third embodiment of the disclosure will be described. FIGS. 9 to 11 illustrate a display device according to the third embodiment of the disclosure. FIG. 9 is a cross-sectional view of a terminal unit of an organic EL display device 50c according to this embodiment. FIG. 9 corresponds to FIG. 3. FIG. 10 is a perspective view showing a step of installing a partition wall member 30c included in the organic EL display device 50c of this embodiment. FIG. 10 corresponds to FIG. 5. FIG. 11 is a perspective view showing a rework step of detaching and remounting the FPC 21 included in the organic EL display device 50c of this embodiment. FIG. 11 corresponds to FIG. 6.

The overall configuration of the organic EL display device 50c is the same as that of the organic EL display device 50a according to the first embodiment except for the configuration of the terminal unit T, and a detailed description thereof will be omitted. Furthermore, like reference signs designate identical constituent features between this embodiment and the first embodiment. Such constituent features will not be elaborated upon.

The organic EL display device 50c includes, as illustrated in FIGS. 9 to 11, a partition wall member 30c instead of the partition wall member 30a included in the organic EL display device 50a of the first embodiment. Furthermore, the organic EL display device 50c includes a metal tape 45b.

In the organic EL display device 50c, as illustrated in FIG. 9, the partition wall member 30c is provided (secured) to a lower surface of the metal tape 45a. Specifically, the partition wall member 30c is integrally formed with the metal tape 45a. Thus, the partition wall member 30c and the metal tape 45a integrally form the metal tape 45b. Note that the partition wall member 30c is formed of the same material as the material of, for example, the spacer 43 included in the IC protective tape 44.

The metal tape 45a has a lower surface formed as an adhesive face. Hence, an upper surface of the partition wall member 30c is adhesively secured to the lower surface of the metal tape 45a. Note that, because the lower surface of the metal tape 45a is adhesive, the upper surface of the partition wall member 30c does not have to be adhesive. Alternately, the upper surface may be adhesive.

Furthermore, the partition wall member 30c may have a lower surface formed as an adhesive face, and the lower surface may be adhesively secured to the FOF-mounted COF 41. Alternatively, as described above, the lower surface may be secured with an adhesive to the FOF-mounted COF 41. Note that the organic EL display device 50c may adopt the modification of the organic EL display device 50a. That is, a side surface of the partition wall member 30c toward the IC chip 11 may be formed as an adhesive face.

Here, as to the partition wall member 30c, adherence of the lower surface (i.e., adherence between the partition wall member 30c and the FOF-mounted COF 41) is higher than adherence of the upper surface (i.e., adherence between the partition wall member 30c and the metal tape 45a). Specifically, the adherence between the lower surface of the partition wall member 30c and the upper surface of the FOF-mounted COF 41 is higher than the adherence between the upper surface of the partition wall member 30c and the lower surface of the metal tape 45a. Hence, exemplary techniques of providing differences in adherence include: a technique of providing the lower surface of the partition wall member 30c with an adhesive face higher in adherence than the lower surface (an adhesive face) of the metal tape 45a; and a technique of applying a curable resin, higher in adherence than the lower surface of the metal tape 45a, to either the lower surface of the partition wall member 30c or a portion, of the upper surface of the FOF-mounted COF 41, for securing the partition wall member 30a.

The organic EL display device 50c of this embodiment can be produced by modifying, as follows, the IC protective tape attaching step and the metal tape attaching step in the method for producing the organic EL display device 50a of the first embodiment. Specifically, the organic EL display device 50c can be produced only by the same steps included in a method for producing a known organic EL display device not including the partition wall member 30c.

### IC Protective Tape Attaching Step

In the method for producing the organic EL display device 50c, the partition wall member 30c is not formed at the IC protective tape attaching step. Specifically, the IC protective tape 44 may simply have to be attached to the upper surface of the IC chip 11. That is, the step eliminates the need for the works of: attaching (adhesively securing), or securing with an adhesive, the partition wall member 30a to the FOF-mounted COF 41; and folding the protruding portion 42b.

### Metal Tape Attaching Step

As illustrated in FIG. 10, at the metal tape attaching step, the metal tape 45b integrally formed of the partition wall member 30c and the metal tape 45a is attached to the FOF-mounted COF 41 with, for example, a jig, so that the partition wall member 30c is disposed between the IC chip 11 and the FPC 21. The metal tape 45b is attached to form the partition wall member 30c. As can be seen, in the method for producing the organic EL display device 50c, the partition wall member 30c is formed not at the IC protective tape attaching step but at the metal tape attaching step.

### Rework Step

In the method for producing the organic EL display device 50c, a procedure of each of the steps included in the rework step is the same as that in the method for producing the organic EL display device 50a.

### Metal Tape Detaching Step

At the metal tape detaching step in the rework step, as illustrated in FIG. 11, the metal tape 45a included in the metal tape 45b is detached from the IC protective tape 44 and the FPC 21. Here, the upper surface and the lower surface of the partition wall member 30c included in the metal tape 45b are different in adherence. Thanks to the difference, the partition wall member 30c is detached from the metal tape 45a and left on the FOF-mounted COF 41. Specifically, the adherence between the lower surface of the partition wall member 30c and the FOF-mounted COF 41 is higher than the adherence between the upper surface of the partition wall member 30c and the metal tape 45a. Thanks to such a feature, the metal tape 45a alone can be detached from the partition wall member 30c while the partition wall member 30c is left adhesively secured, or secured with an adhesive, to the FOF-mounted COF 41. As can be seen, in the method for producing the organic EL display device 50c, the metal tape 45a is detached from the FOF-mounted COF 41 in the sequence of rework step. After that, the partition wall member 30c detached and separated from the metal tape 45a stays on the FOF-mounted COF 41. As to the organic EL display device 50c, the partition wall member 30c is formed when the metal tape 45a is detached.

### Advantageous Effects

As described above, the organic EL display device 50c according to this embodiment can achieve the same advantageous effects described in the first embodiment. Furthermore, in addition to the above advantageous effects, the organic EL display device 50c can achieve advantageous effects below.

In the organic EL display device 50c, the partition wall member 30c is formed integrally with the metal tape 45a. Such a feature eliminates the need for separately providing the partition wall member 30c. In other words, the feature can reduce the number of components.

In the method for producing the organic EL display device 50c, the partition wall member 30c and the metal tape 45a integrally form the metal tape 45b. The metal tape 45b may be used when a known metal tape attaching step is carried out. That is, the organic EL display device 50c can be produced only by the same steps, including the IC protective tape attaching step, as those of a method for producing a known organic EL display device not including the partition wall member 30c. Such a feature can further improve efficiency in the steps.

### Fourth Embodiment

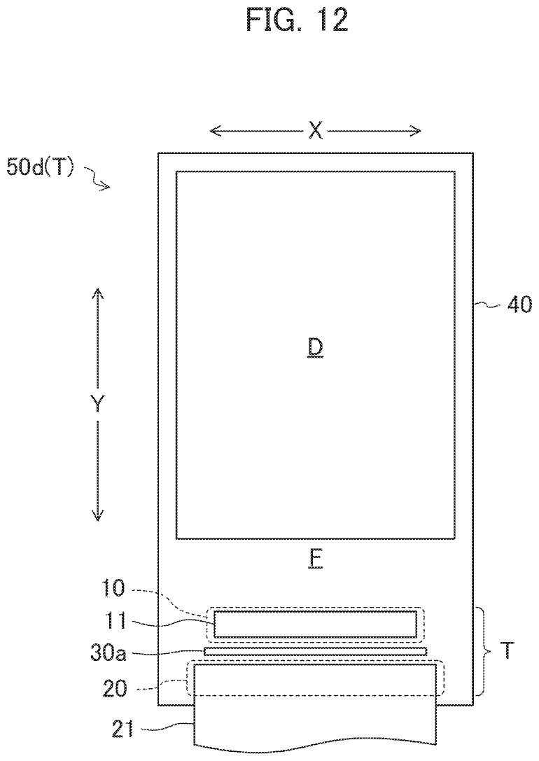

Next, a fourth embodiment of the disclosure will be described. FIG. 12 illustrates a display device according to the fourth embodiment of the disclosure. FIG. 12 is a plan view of a schematic configuration of an organic EL display device 50d according to this embodiment. FIG. 12 corresponds to FIG. 1.

The overall configuration of the organic EL display device 50d is the same as that of the organic EL display device 50a according to the first embodiment except for the configuration of the terminal unit T, and a detailed description thereof will be omitted. Furthermore, like reference signs designate identical constituent features between this embodiment and the first embodiment. Such constituent features will not be elaborated upon.

In the organic EL display device 50a of the first embodiment, the IC chip 11 and the FPC 21 are mounted through the flexible substrate 41 connected to the display panel 40 (i.e., the terminal unit T in the picture-frame region F of the display panel 40). Whereas, in the organic EL display device 50d of this embodiment, as illustrated in FIG. 12, the IC chip 11 and the FPC 21 are directly mounted on the display panel 40 (i.e., the terminal unit T in the picture-frame region F of the display panel 40). Hence, in the organic EL display device 50d, the partition wall member 30a is also directly mounted on the display panel 40. That is, the organic EL display device 50d does not include the flexible substrate 41.

Note that the organic EL display device 50d may adopt the modification of the organic EL display device 50a, and any configurations of the organic EL display devices 50b and 50c. That is, the organic EL display device 50d may include either the partition wall member 30b or the partition wall member 30c instead of the partition wall member 30a.

The organic EL display device 50d of this embodiment can be produced by the steps in the method for producing the organic EL display device 50a of the first embodiment. In each of the steps, the flexible substrate 41 (the COF 41) is read as the display panel 40 (i.e., the terminal unit T in the picture-frame region of the display panel 40). Furthermore, the method for producing the organic EL display device 50d includes an IC chip mounting step before the FPC mounting step.

### IC Chip Mounting Step

The IC chip mounting step involves thermocompression-bonding of the IC chip 11 on the terminal unit T of the display panel 40 through the first conductive material 10. That is, the IC chip mounting step can be referred to as a COP (Chip on Plastic) forming step of forming a COP in which the IC chip 11 is directly mounted on the display panel 40.

### FPC Mounting Step

On the display panel 40 (the COP) with the IC chip 11 mounted thereon, the FPC 21 is thermocompression-bonded through the second conductive material 20.

### Advantageous Effects

As described above, the organic EL display device 50d according to this embodiment can achieve the same advantageous effects described in the first embodiment.

### OTHER EMBODIMENTS

In each of the embodiments, the organic EL display device is exemplified as a display device. The disclosure can be applied to a display device including a plurality of light-emitting elements driven by currents. For example, the disclosure can be applied to a display device including quantum-dot light-emitting diodes (QLEDs); that is, light-emitting elements including layers containing quantum dots.

### INDUSTRIAL APPLICABILITY

As described above, the disclosure is useful for a flexible display device.

1. A display device, comprising:
an IC chip mounted through a first conductive material; and
an FPC mounted through a second conductive material,
wherein the IC chip and the FPC are arranged side by side, and
between the IC chip and the FPC, a partition wall member is provided to separate the first conductive material and the second conductive material from each other.

2. The display device according to claim 1,
wherein the partition wall member is secured to a substrate on which the IC chip and the FPC is mounted.

3. The display device according to claim 1,
wherein the partition wall member is shaped into a shape of tape extending in a direction perpendicular to a direction in which the IC chip and the FPC face each other.

4. The display device according to claim 1, further comprising
an IC protective tape provided to cover the IC chip,
wherein the IC protective tape has a spacer surrounding end portions of the IC chip except for an end portion facing the FPC, and
the partition wall member is formed of a same material as a material of the spacer.

5. The display device according to any claim 1, further comprising
an IC protective tape provided to cover the IC chip,
wherein the IC protective tape has an end portion toward the FPC, and the end portion is provided with a protruding portion, and
the partition wall member is formed of the protruding portion folded along a folding axis in a direction perpendicular to a direction in which the IC chip and the FPC face each other.

6. The display device according to claim 5, wherein
a slit is formed along the folding axis.

7. The display device according to claim 1, further comprising:
an IC protective tape provided to cover the IC chip; and
a metal tape provided on the IC protective tape to cover the IC chip,
wherein the partition wall member is integrally formed with the metal tape.

8. The display device according to claim 7,
wherein the metal tape has a lower surface formed as an adhesive face, and
an upper surface of the partition wall member is adhesively secured to the lower surface of the metal tape.

9. The display device according to claim 8,
wherein adherence between the partition wall member and the substrate on which the IC chip and the FPC are mounted is higher than adherence between the partition wall member and the metal tape.

10. The display device according to claim 7,
wherein the IC protective tape has a spacer surrounding end portions of the IC chip except for an end portion facing the FPC, and
the partition wall member is formed of a same material as a material of the spacer.

11. The display device according to claim 1,
wherein a distance between the IC chip and the FPC is more than, or equal to, a thickness of the partition wall member, and less than, or equal to, 4 mm.

12. The display device according to claim 1,
wherein the partition wall member has a thickness of 150 μm or more.

13. The display device according to claim 1,
wherein the partition wall member has a side surface toward the IC chip, and the side surface is formed as an adhesive face.

14. The display device according to claim 1, further comprising:
a display panel including a display region, and a picture-frame region provided around the display region; and
a flexible substrate connected to an end portion of the picture-frame region of the display panel,
wherein the IC chip and the FPC are mounted on the flexible substrate.

15. The display device according to claim 1, further comprising
a display panel including a display region, and a picture-frame region provided around the display region,
wherein the IC chip and the FPC are mounted on an end portion of the picture-frame region of the display panel.

16. A method for producing a display device, the display device including:
an IC chip mounted through a first conductive material;
an FPC mounted side by side with the IC chip through a second conductive material;
a partition wall member provided between the IC chip and the FPC, and separating the first conductive material and the second conductive material from each other; and
an IC protective tape provided to cover the IC chip, the method comprising
an IC protective tape attaching step of attaching the IC protective tape to the IC chip,
wherein the partition wall member is formed at the IC protective tape attaching step.

17. The method for producing the display device according to claim 16,
wherein the IC protective tape has an end portion toward the FPC, and the end portion is provided with a protruding portion, and
at the IC protective tape attaching step, the partition wall member is formed of the protruding portion folded along a folding axis in a direction perpendicular to a direction in which the IC chip and the FPC face each other.

18. The method for producing the display device according to claim 16, further comprising
a rework step of detaching the FPC if the FPC is defective and remounting a new FPC,
wherein, at the rework step, the partition wall member is found.

19. A method for producing a display device, the display device including:
an IC chip mounted through a first conductive material;
an FPC mounted side by side with the IC chip through a second conductive material;
a partition wall member provided between the IC chip and the FPC, and separating the first conductive material and the second conductive material from each other;
an IC protective tape provided to cover the IC chip; and
a metal tape provided on the IC protective tape to cover the IC chip,
the partition wall member being integrally formed with the metal tape, and the method comprising:
an IC protective tape attaching step of attaching the IC protective tape to the IC chip; and
a metal tape attaching step of attaching the metal tape to the IC chip to which the IC protective tape is attached,
wherein, at the metal tape attaching step, the metal tape is attached to form the partition wall member.

20. The method for producing the display device according to claim 19, further comprising
a rework step of detaching the FPC if the FPC is defective and remounting a new FPC,
wherein the rework step includes a metal tape detaching step of detaching the metal tape, and
after the metal tape is detached at the metal tape detaching step, the partition wall member is detached from the metal tape and left.

21. (canceled)

22. (canceled)
